(19) United States
(12) Patent Application Publication
(10) Pub. No.: US 2015/0124415 A1
(43) Pub. Date: May 7, 2015

(54) PROTECTIVE COVERING FOR WEARABLE DEVICES

(71) Applicants: Dileep Goyal, Fremont, CA (US); Andrew Dawn, Roseville, CA (US); William Maginn, San Diego, CA (US); Hari Chakravarthula, San Jose, CA (US)

(72) Inventors: Dileep Goyal, Fremont, CA (US); Andrew Dawn, Roseville, CA (US); William Maginn, San Diego, CA (US); Hari Chakravarthula, San Jose, CA (US)

(73) Assignee: AliphCom, San Francisco, CA (US)

(21) Appl. No.: 14/073,550

(22) Filed: Nov. 6, 2013

(51) Int. Cl. H05K 1/18; H05K 3/36

(52) U.S. Cl. CPC H05K 1/18; H05K 3/361
USPC 361/749; 29/830

(57) ABSTRACT

Embodiments of the present application relate generally to personal electronics, portable electronics, wearable electronics, and more specifically to a structure and method for a protective covering for a wearable device. Interior and exterior structures of the wearable device are configured to be flexed into a configuration and to retain the configuration after the flexing. Interior structure may include a first flexible substrate having a first relaxation structure and a second flexible substrate having a second relaxation structure. Components or other structures may be connected with the first and/or second flexible substrates. The first and second relaxation structures may be positioned relative to each other to define a flexure point. At least one flexible and electrically non-conductive cover, that may undergo shirking, may conformally cover at least a portion of the interior structure. A flexible overmolding may be formed over the cover and may comprise the exterior structure.

### CROSS-REFERENCE TO RELATED APPLICATIONS

This application is related to the following applications: U.S. patent application Ser. No. 13/181,512, filed on Jul. 12, 2011, having Attorney Docket No. ALI-003, and titled “Media Device, Application, And Content Management Using Sensory Input”; and U.S. patent application Ser. No. 13/898,451, filed on May 20, 2013, having Attorney Docket No. ALI-003CIP1, and titled “Media Device, Application, And Content Management Using Sensory Input Determined By A Data-Capable Watch Band” all of which are hereby incorporated by reference in their entirety for all purposes.

### FIELD

These present application relates generally to personal electronics, portable electronics, wearable electronics, and more specifically to systems, electronics, structures and methods for wearable devices.

### BACKGROUND

Electronic and structural systems used in wearable devices ought to be designed to withstand the rigors of use and repeated cycles of bending, flexing, strapping on, un-strapping; as well as environmental conditions such as temperature, humidity, moisture, sweat, shock, and vibration, just to name a few. Typically, processes and materials used in the manufacture of a wearable device may include the use of glue or adhesives to secure and/or protect internal components of the wearable device. Additionally, solder may be used to electrically couple wires or other components (e.g., surface mount devices) of the wearable device. In that a wearable device may be configured to be flexible for user by its users, designing flexibility in the wearable devices may require the use of flexible structures such as flexible circuit boards and other flexible materials that may be selected to retain a shape when the wearable device is flexed into a specific configurations, such as being flexed to wrap around a portion of a user's body (e.g., wrist, arm, ankle, leg, neck, head, etc.). However, the repeated flexing of the wearable device may lead to failure modes such as electrical shorts or opens in wires, solder joints, traces in the flexible circuit board, infiltration of glue, adhesives, or the like into components such as batteries or other electrical or electrical/mechanical components, just to name a few. Moreover, application of glue, adhesives, or the like may require manual trimming of excess material after it has dried or otherwise cured, leading to increased labor cost and manufacturing time. In some applications one or more covers or moldings may be applied to a wearable device to cover and protect already fabricated inner portions of the wearable device. Components of the inner portions may need to be covered or otherwise protected from subsequent molding operations that may result in damage to those components due to heat and/or infiltration of the molding material, for example. Components positioned at locations within the wearable device that will be subjected to forces from flexing may eventually fail due to constrained movement when the wearable device is flexed. For examples, wires or electrical traces may fail if they are not free to flex as the wearable device is flexed. Restricted movement of the wires/traces may lead to broken solder joints, breakage, shorts, or intermittent continuity.

Accordingly, there is a need for systems, electronics, structures and methods for fabrication of wearable devices that enable reliable manufacture and operation of wearable devices.

### BRIEF DESCRIPTION OF THE DRAWINGS

Various embodiments or examples (“examples”) of the present application are disclosed in the following detailed description and the accompanying drawings. The drawings are not necessarily to scale:

FIGS. 1A-1B depict a cross-sectional view of a flexible substrate including a first relaxation structure and a flexible dielectric including a second relaxation structure, according to an embodiment of the present application;

FIGS. 1C-1D depict cross-sectional views of a flexible substrate and flexible dielectric that include a plurality of first relaxation structures and second relaxation structures, according to an embodiment of the present application;

FIG. 2A depicts a top plan view of a flexible dielectric and associated structures, according to an embodiment of the present application;

FIG. 2B depicts a cross-sectional view of a flexible dielectric, according to an embodiment of the present application;

FIG. 3A depicts a top plan view of a flexible dielectric and examples of associated structures, according to an embodiment of the present application;

FIG. 3B depicts a cross-sectional view of a flexible dielectric and examples of associated structures, according to an embodiment of the present application;

FIGS. 3C-3D depict top plan views of a flexible dielectric and associated structures, according to an embodiment of the present application;

FIGS. 4A-4B depict top plan views of a flexible dielectric and associated structures, according to an embodiment of the present application;

FIGS. 5A-5E depict cross-sectional views of a flexible substrate, a flexible dielectric, and associated structures, according to an embodiment of the present application;

FIG. 6A depicts one example of a mandrel, according to an embodiment of the present application;

FIGS. 6B-6G depict examples of different configurations for a mandrel, according to an embodiment of the present application;

FIG. 7A depicts a cross-sectional view of one example of a flexible and electrically non-conductive cover, according to an embodiment of the present application;

FIG. 7B depicts one example of a flexible and electrically non-conductive cover after shrinking in a dimension, according to an embodiment of the present application;

FIG. 8A depicts a cross-sectional view of another example of a flexible and electrically non-conductive cover, according to an embodiment of the present application;

FIG. 8B depicts a cross-sectional view of one example of a plurality of sections of a flexible and electrically non-conductive cover, according to an embodiment of the present application;

FIGS. 9A-9C depict cross-sectional views of examples of alternative configurations for a relaxation structure connected with a flexible substrate, according to an embodiment of the present application;

FIG. 10A depicts a profile view of one example of a partially assembled wearable device, according to an embodiment of the present application;

FIG. 10B depicts a cross-sectional view of one example of a partially assembled wearable device, according to an embodiment of the present application;

FIG. 10C depicts a cross-sectional view of one example of a partially assembled wearable device including a flexible substrate, a flexible dielectric, and a plurality of flexure points, according to an embodiment of the present application;

FIG. 10D depicts a cross-sectional view of one example of the configuration depicted in FIG. 10C at a subsequent stage of fabrication, according to an embodiment of the present application;

FIG. 11 depicts a profile view of one example of a partially assembled wearable device including a flexible and electrically non-conductive cover after a shrinking process, according to an embodiment of the present application;

FIG. 12 depicts a profile view of one example of a flexible overmolding, according to an embodiment of the present application;

FIG. 13 depicts views of different examples of wearable devices configured to be flexibly worn on a structure, according to an embodiment of the present application;

FIG. 14 depicts a cross-sectional view of a wearable device flexibly mounted to a portion of a structure, according to an embodiment of the present application; and

FIG. 15 depicts one example of a flow diagram for a method for fabricating a wearable device, according to an embodiment of the present application.

### DETAILED DESCRIPTION

Various embodiments or examples may be implemented in numerous ways, including as a system, a process, an apparatus, a user interface, or a series of program instructions on a non-transitory computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying drawing FIGS. The detailed description is provided in connection with such examples, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For clarity, technical material that is known in the technical fields related to the examples has not been described in detail to avoid unnecessarily obscuring the description.

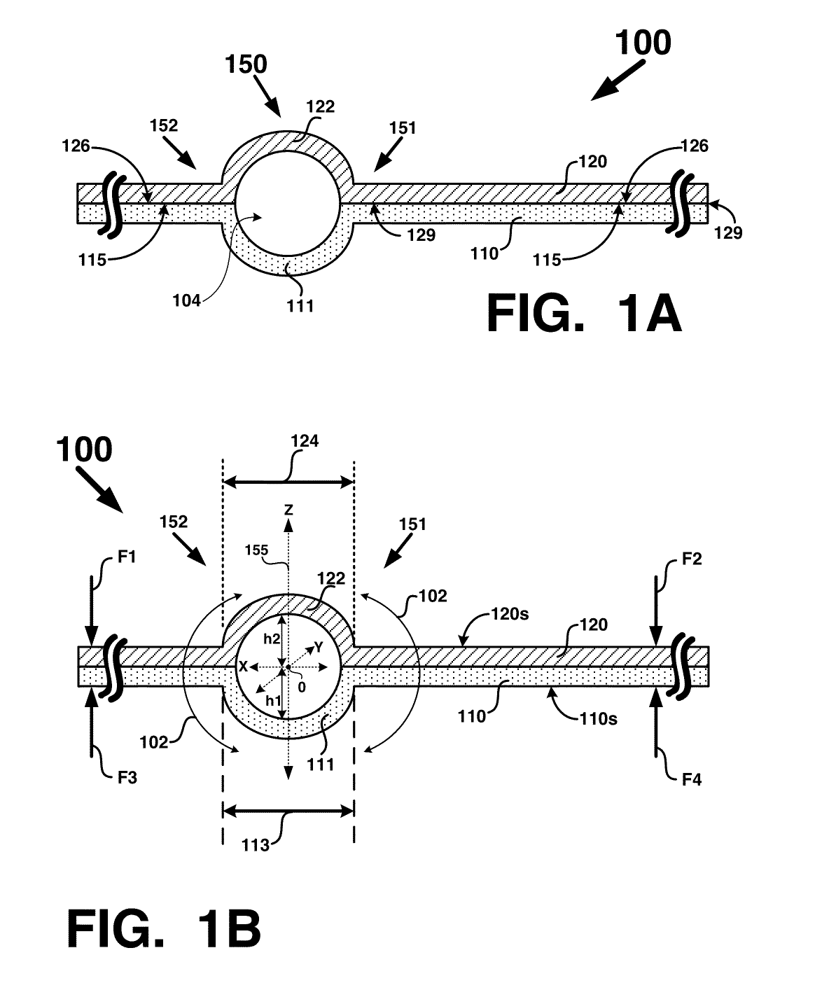

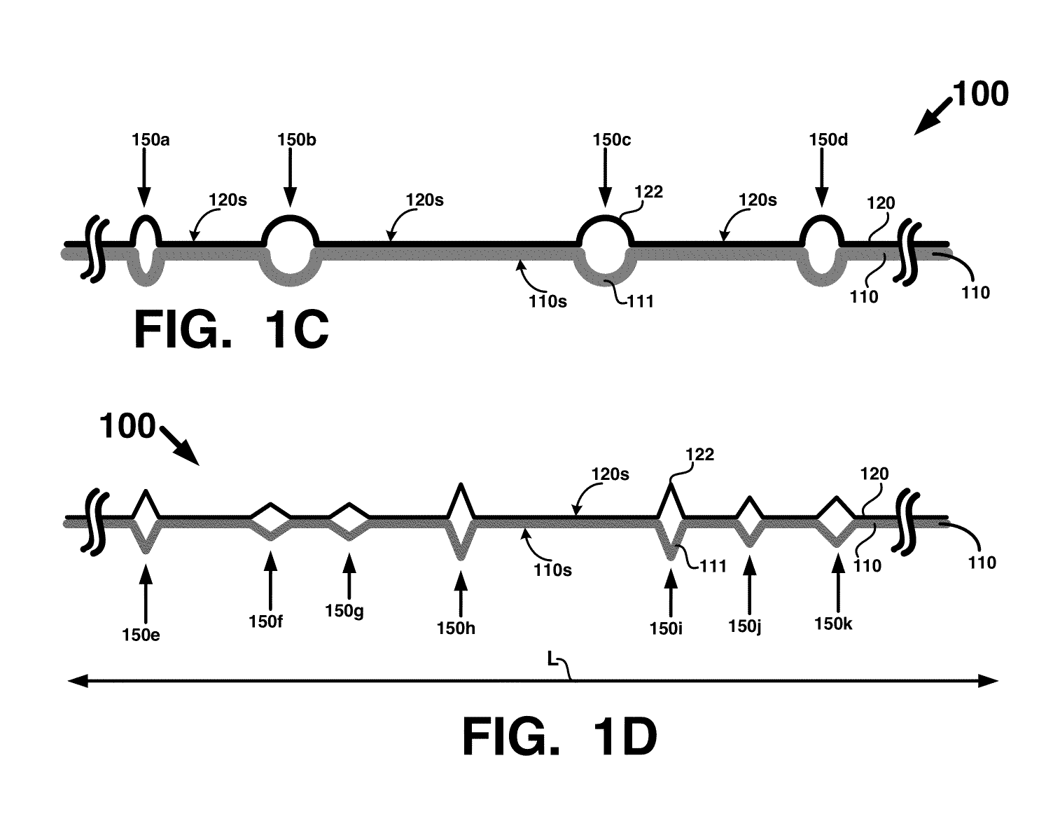

FIGS. 1A-1B depict a cross-sectional view of a flexible substrate 110 including a first relaxation structure 111 and a flexible dielectric 120 including a second relaxation structure 122. The first and second relaxation structures (111, 122) may be positioned relative to each other for form a flexure point 150 in a wearable device 100. Here, a finished wearable device 100 is not depicted and subsequent FIGS. will depict the wearable device 100 at different stages of fabrication leading up to a manufactured (e.g., finished) wearable device 100. Wearable device 100 may include a plurality of flexure points 150 that are defined by pluralities of first and second relaxation structures (111, 122). Components may be positioned on one or both sides (151, 152) of the flexure point 150 and those components may be positioned on surfaces 110s and/or 120s of the substrate 110 and dielectric 120. Substrate 110 and dielectric 120 may be mechanically coupled with each other to prevent relative motion between the substrate 110 and dielectric 120 at one or more locations. For example, surfaces 115 and 126 may be connected or otherwise mechanically coupled with each other using a variety of techniques including but not limited to gluing, fastening (e.g., using a fastener), stapling, adhesive bonding, welding, friction stir welding, ultrasonic welding, clamping, and crimping, just to name a few. As one example, glue or an adhesive material may be applied between an interface 129 between surfaces 115 and 126 and allowed to cure to couple the substrate 110 with the dielectric 120. The relative positioning of the first and second relaxation structures (111, 122) may define a space 104 between the relaxation structures (111, 122) having a shape that may be determined in part by shapes and/or contours of the relaxation structures (111, 122). In some applications a structure such as a mandrel (not shown), for example, may be positioned in the space 104 as will be described below.

In FIG. 1B, the first and second relaxation structures (111, 122) allow for flexing 102 (e.g., flexure, bending, curving, twisting, being bent or curved, etc.) of the substrate 110 and dielectric 120 proximate the flexure point 150 in response to one or more forces F1-F4 are applied to the wearable device 100, such as forces required to flex or bend the wearable device 100 into a configuration for use by a user of the wearable device 100. An example of a configuration may include flexure caused by wrapping or un-wrapping the wearable device 100 from a wrist, ankle, neck, torso, or other portion of a body or structure. The user may not be a human being and in some applications the wearable device 100 may be worn by an inanimate structure (e.g., a post). Although the first and second relaxation structures (111, 122) are depicted as having a curved or arcuate shape or profile, the present application is not limited to the shapes and/or profiles depicted. Moreover, the first and second relaxation structures (111, 122) need not have the same shape and/or profile. A span 113 and 124 (e.g., a distance across from 151 to 152) for the first and second relaxation structures (111, 122) respectively may be the same or different. A relative position between the first and second relaxation structures (111, 122) may not be symmetric. Using X-Y-Z axes 155 as a reference point for purposes of explanation, first and second relaxation structures (111, 122) may be symmetrically positioned relative to each other or may be positioned in displaced relationship relative to each other. For example, a displaced positioning may comprise second relaxation structure 122 being shifted to the left or to the right on the X-axis relative to the first relaxation structure 111. As another example, the displaced positioning may comprise the first relaxation structure 111 may be shifted into or out of the drawing sheet along the Y-axis relative to the second relaxation structure 122. Along the Z-axis, a height (h2, h1) of the first and second relaxation structures (111, 122) (e.g., as measured from an origin 0) may be the same or different.

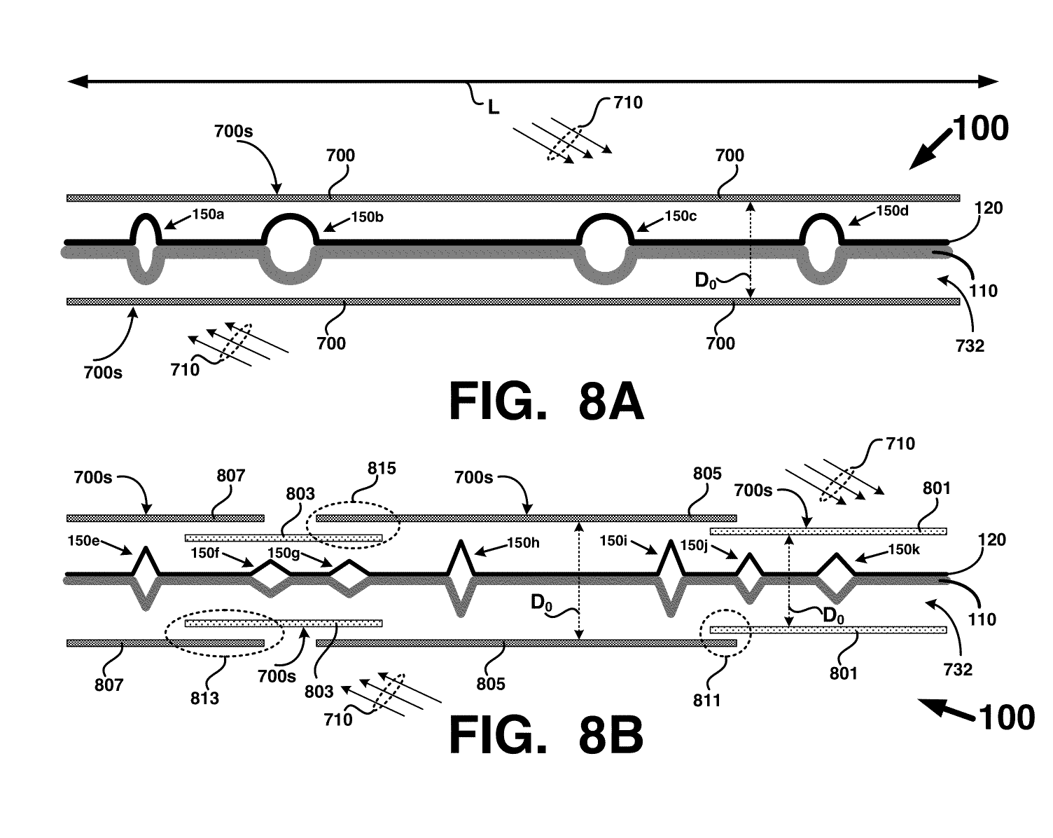

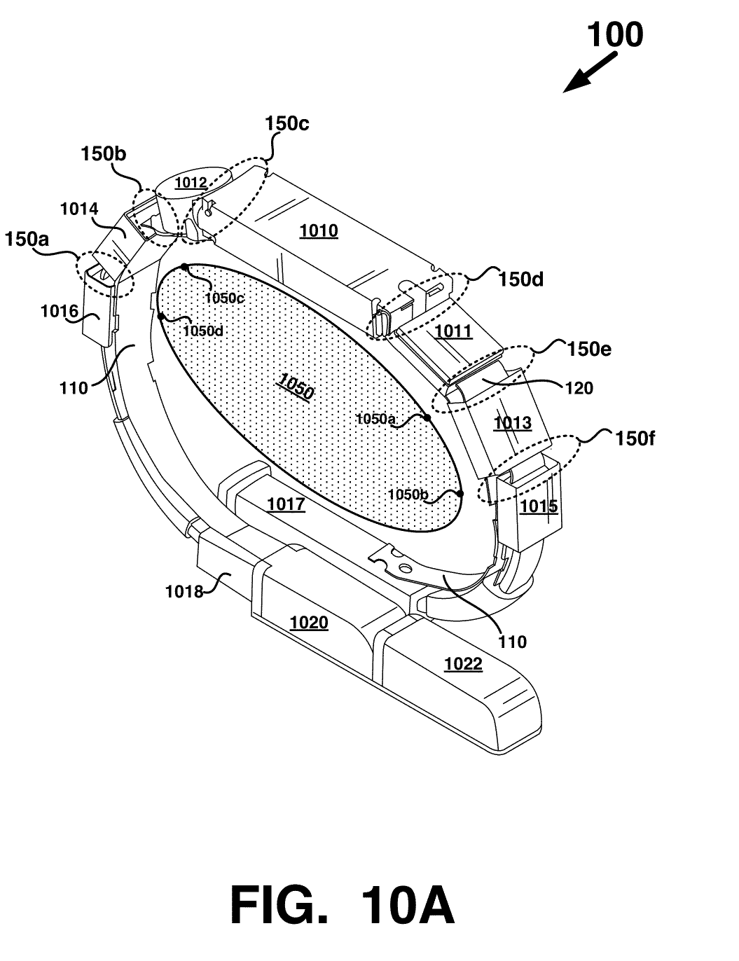

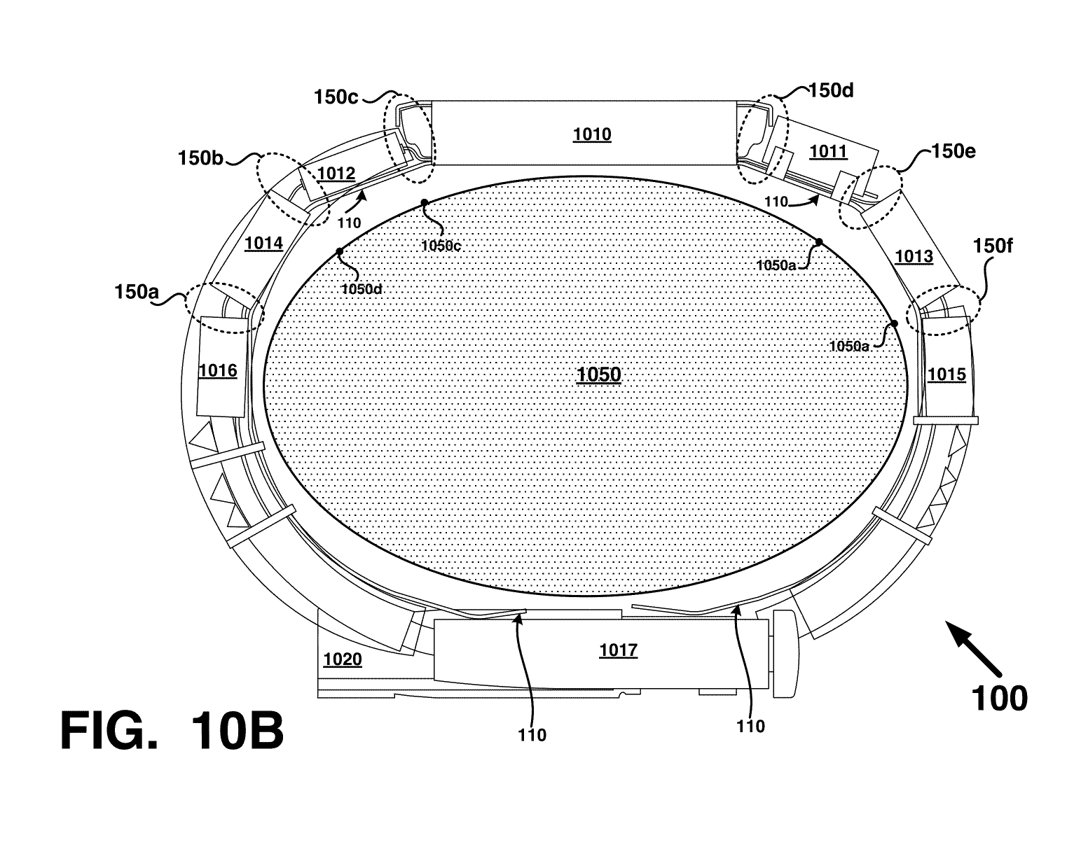

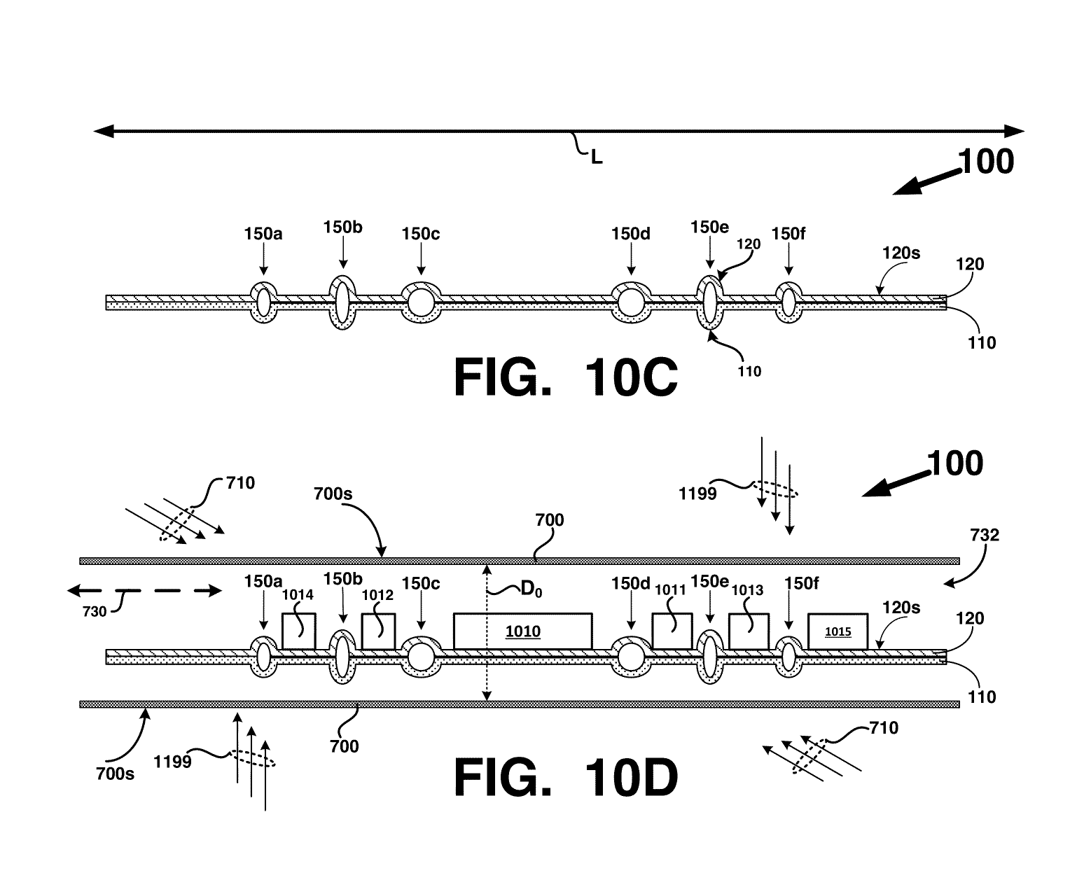

FIGS. 1C-1D depict cross-sectional views of flexible substrate 110 and flexible dielectric 120 including a plurality of first relaxation structures and second relaxation structures that define a plurality of flexure points denoted as 150a-150d in FIG. 1C and 150e-150k in FIG. 1D. In FIG. 1C the first and second relaxation structures (111, 122) include arcuate profiles (e.g., curved, oval-shaped, or semicircular shaped); whereas, in FIG. 1C the first and second relaxation structures (111, 122) include angular profiles (e.g., triangular or sloped). Actual profiles, shapes and dimensions will be application dependent and are not limited to the examples described herein. As will be described below, one or more flexure points, such as those depicted in FIGS. 1C-1D may be positioned at predetermined locations in wearable device 100 to accommodate flexing of the wearable device 100 and/or to prevent damage to components (e.g., wiring, conductive traces, or structure) of the wearable device 100 that may be caused by flexing. In FIGS. 1C-1D (see also FIGS. 8A-8B and 10C-10D) the wearable device 100 may have an overall length L configured to accommodate mounting the device 100 on a selected portion of a user's body (e.g., the arms, the legs, the neck, the chest, the head, the abdomen, etc.). For example, to fit around the circumference or perimeter of a wrist or ankle, length L may be a first length and have M flexure points 150; whereas, for larger portions of a body such as a circumference or perimeter of a torso, neck, thigh, head, calf or bicep, length L may be a second length that is longer than the first length and have N flexure points 150, where N may be larger than M.

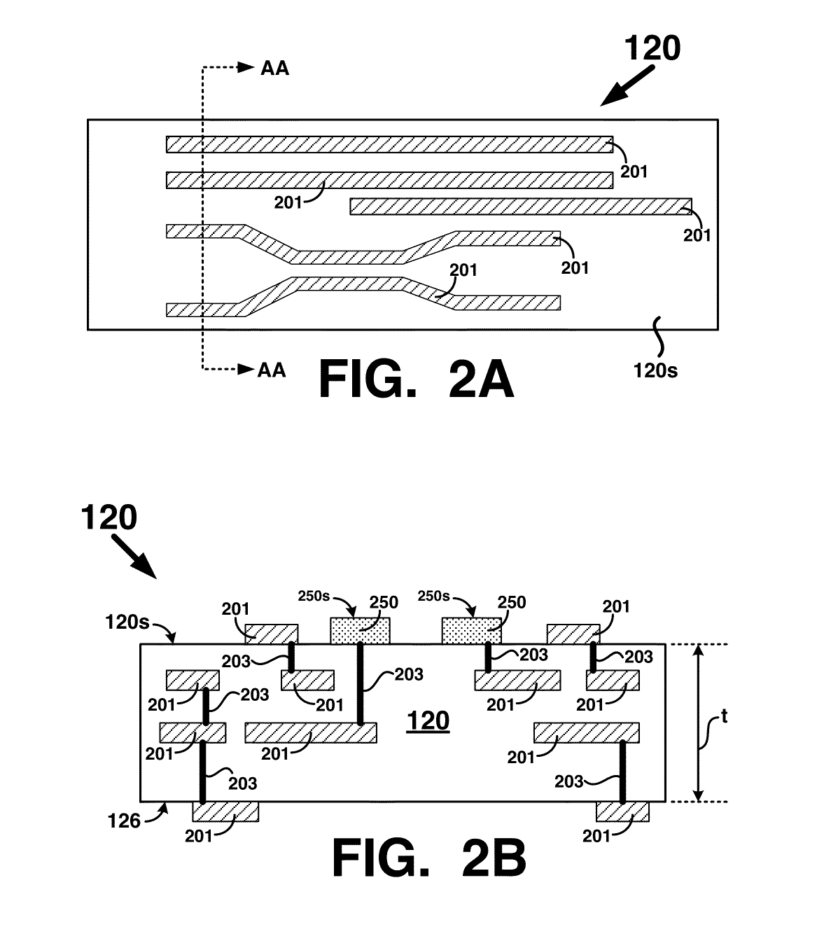

Moving now to FIG. 2A where a top plan view of the flexible dielectric 120 and associated structures are depicted. Flexible dielectric 120 may include one or more structures including but not limited to electrically conductive traces, wire(s), bonding pads, strain reliefs, vias, throughs, electrical components, mechanical components, electro-mechanical components, MEMS components, power supplies (e.g., a battery), vibration motors/engines, gyroscopes, accelerometers, microphones, speakers, indicator lights (e.g., LED's), switches/buttons, just to name a few. In FIG. 2A, a plurality of electrically conductive traces 201 are depicted, but there may be more or fewer traces 201. Traces 201 may be positioned on a surface 120s or other position on dielectric 120. Traces 201 may be made from and electrically conductive material including but not limited to metal, metal alloys, electrically conductive inks, dyes, paste, nanotubes, just to name a few.

In FIG. 2B, a cross-sectional view of dielectric 120 along dashed line AA-AA of FIG. 2B depicts examples of structures that may be included in dielectric 120. Surface 120s may include one or traces 201 and one or more electrically conductive nodes 250 (e.g., bonding pads). A surface 250s of nodes 250 may be configured to receive another electrically conductive structure, such as a wire, solder, or both, for example. Another surface 126 may include traces 201. An interior of dielectric 120 may also include one or more traces 201 and may include one or more vias 203 for electrically coupling structures such as traces 201 and nodes 250. Dielectric 120 may have a thickness t that is application dependent. For example, thickness t may be about 2 mm or less. Flexible dielectric (FD) 120 may comprises a material including but not limited to flexible printed circuitry (FPC), flat flexible cable (FFC), a flexible circuit board, and other forms of flexible substrates made from a dielectric material and optionally include structures such as electrically conductive structures, just to name a few.

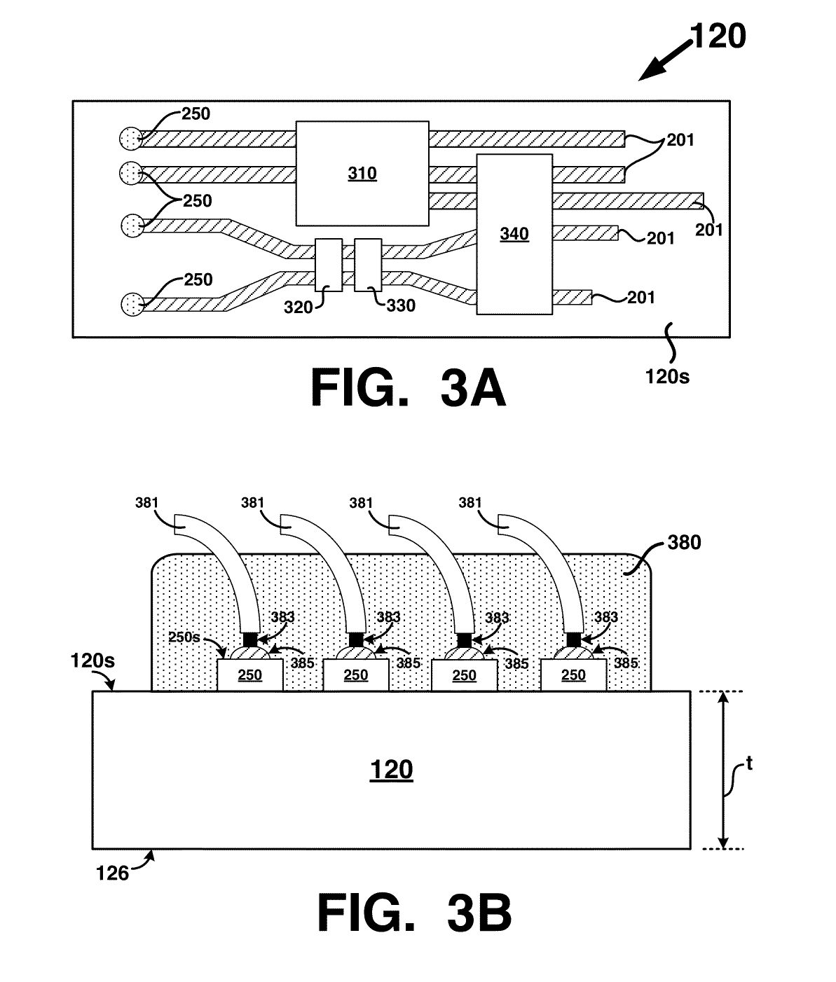

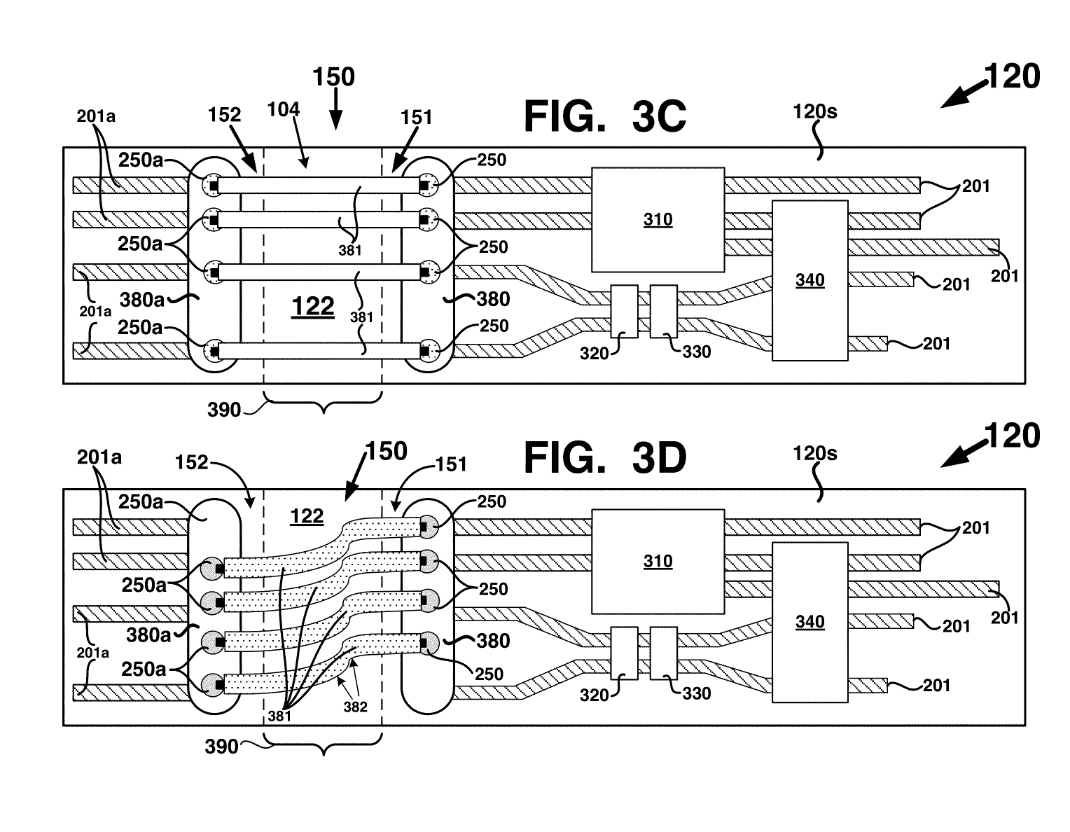

FIGS. 3A and 3B depict top plan and cross-sectional views respectively of FD 120 and examples of associated structures that may optionally be included with FD 120. FD 120 may include one or more of nodes 250, traces 201, and components 310-340. Components 310-340 may be electrically coupled with traces 201 via soldering (e.g., surface mount) or other processes. One or more of traces 201 may be electrically coupled with nodes 250 and the nodes 250 may be electrically coupled with other structures such as wires and/or solder bumps or the like. Associated structures may be positioned on surface 120s.

In FIG. 3B, the cross-sectional view depicts an example where nodes 250 have wire ends 383 of wires 381 electrically coupled with the nodes 250 using solder 385. Moreover, an encapsulating structure 380 (e.g., made from an electrically non-conductive material) may be formed on FD 120 and may partially or completely surround one or more structures such as nodes 250, solder 385, wire ends 383 and a portion of wires 381. Wires 318 may be insulated wires or may be un-insulated wires. Encapsulating structure 380 may be configured to protect the structures it encapsulates, to provide mechanical stability and/or isolation, to provide strain relief, protect against moisture and/or corrosion that may be caused by chemicals, fluids, or the like, or to protect the encapsulated structures from subsequent fabrication steps, just to name a few. In some applications, one or both sides (151, 152) of flexure point 150 may include the associated structure depicted in FIGS. 3A and/or 3B.

FIGS. 3C and 3D depict top plan views of FD 120 and additional examples of associated structures that may be optionally included with FD 120. In FIGS. 3C and 3D, second relaxation region 122 is denoted in dashed lines and associated components that may be included with FD 120 are depicted on both sides (151, 152) of flexure point 150, although in other examples the associated components may be positioned on only one of the sides (151, 152). Referring now to FIG. 3C, a span 390 across second relaxation region 122 is straddled by wires 381 which terminate at nodes 250 and 250a in encapsulating structures 380 and 380a. As will be described below, wires 381 may have a contour, profile or shape (e.g., arcuate shape) across span 390 that approximately matches a contour, profile or shape of the second relaxation structure 122. Wires 381 or other electrically conductive structures may be pre-shaped to include the contour, profile or shape, be bent or otherwise mechanically manipulated to have the contour, profile or shape, for example. In FIG. 3C wires 381 and nodes 250 are depicted as being approximately aligned with one another with wires 381 straddling span 390 in an approximately straight line or linear path. However, the wires 381, nodes 250 or other associated structures on FD 120 may not be so configured and may not be aligned or laid out in straight lines.

In FIG. 3D, nodes 250 and 250a are not aligned with each other and wires 381 are dressed across span 390 in a non-linear path and each wire 381 may include bends or folds 382 along its length. Dressing wires 381 or other electrically conductive structures that straddle the second relaxation region 122 may be used for a variety of purposes including but not limited to preventing the wires from kinking or having sharp bends that may cause the wire to fail due to opens, or intermittent continuity, to set a profile in the wires as they straddle the span 390, and to create or relieve tension in the wires, just to name a few. In FIGS. 3C-3D, the portion of FD 120 that forms the second relaxation region 122 may include electrically conductive traces such as those depicted 2A-3D (e.g., like traces 201) that may supplement or replace wires 381. In other applications the portion of FD 120 that forms the second relaxation region 122 may not include traces. Traces may be exclude from second relaxation region 122 to prevent fatigue from repeated flexing of the second relaxation region 122 from causing potential mechanical failure of the traces that could lead to intermittent continuity, open circuits or short circuits, for example.

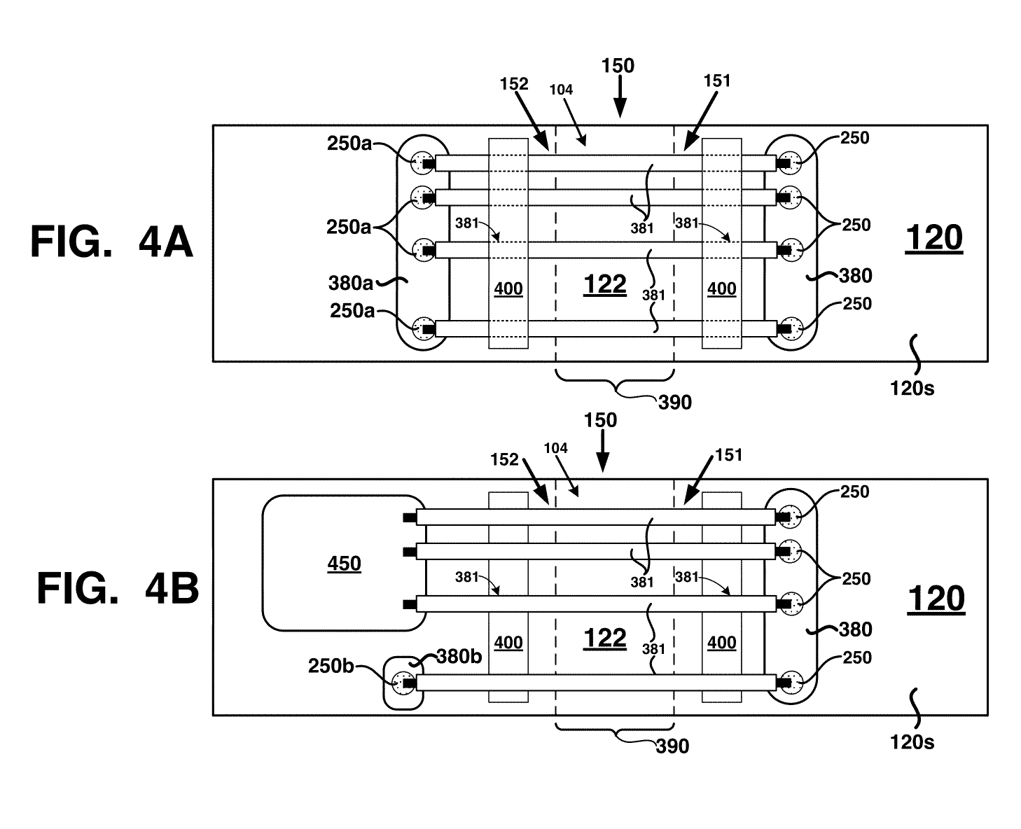

Turning now to FIGS. 4A-4B where top plan views of FD 120 and associated structures includes a strain relief 400 that may be positioned on one or both of the sides (151, 152). Strain relief 400 is in contact with a portion of one or more of the wires 381 and may be operative to restrain movement of the wires 381, prevent the wires 381 from being stressed, or prevent wire ends 383 from being pulled from their respective nodes 250 and/or from becoming unsoldered, for example. The strain relief 400 may be positioned between the nodes 250 and/or encapsulating structure 380 and the sides (151, 152) of the second relaxation region 122.

In FIG. 4B, some of the wires 381 may not terminate at a node 250 and may instead be electrically coupled with a component 450 or other structure on either side (151, 152) of the second relaxation region 122. For example, component 450 on the second side 152 may be a power source such as a battery and three of the wires 381 that straddle span 390 may be electrically coupled with component 450 and another wire 381 may be electrically coupled with a node 250b in encapsulating structure 380b. Strain relief 400 and second side 152 may prevent the wires 381 from being disconnected and/or dislodged from component 450 due to flexing at flexure point 150.

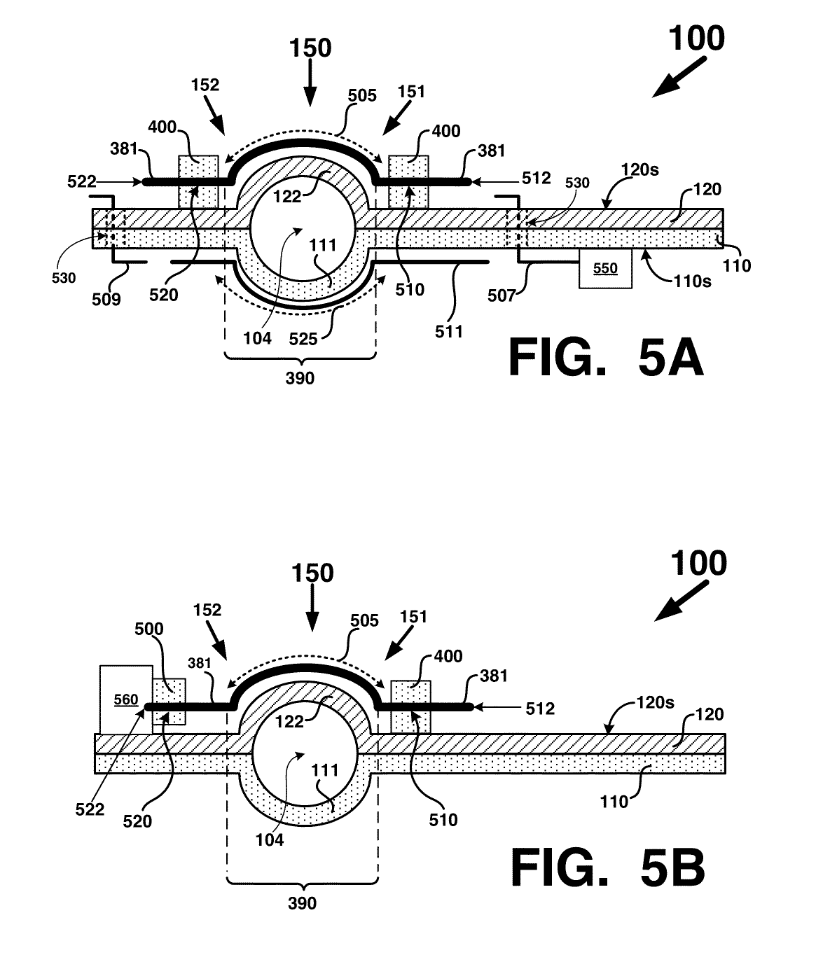

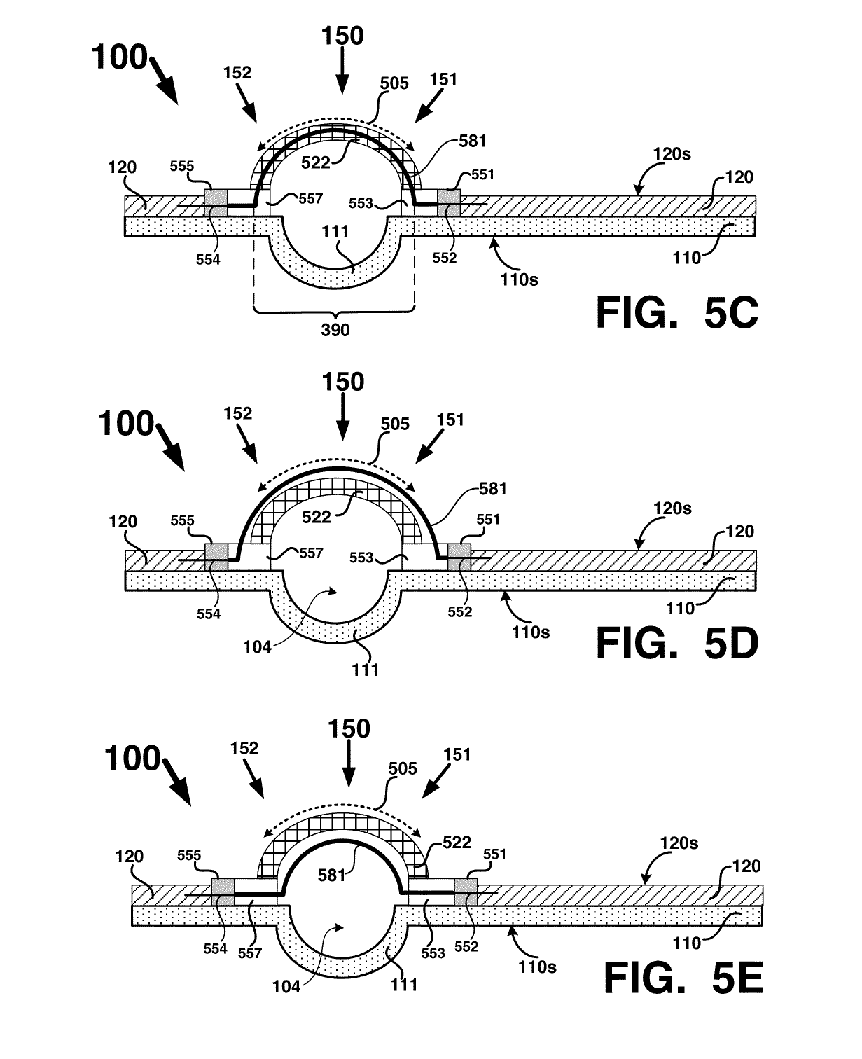

Reference is now made to FIGS. 5A-5E were cross-sectional views depict flexible substrate (FS) 110, FD 120 and associated structures including strain reliefs 400. In FIG. 5A, wire 381 is depicted straddling span 390 and having portions of wire 381 in contact (510, 520) with strain reliefs 400 and both sides (151, 152) of second relaxation region 122. Ends (512, 522) of wire 381 may be electrically terminated in any manner including but not limited to those discussed above, such as soldering to nodes 250, crimping, splicing, etc. Here, wire 381 may have a profile 505 over its span 390 of the second relaxation region 122 and that profile may or may not approximately match a profile of the second relaxation region 122. Optionally, FD 120 and FS 110 may include vias, thrus, or the like denoted here as 530 and a structure such as a wire, electrically conductive trace or other may be routed or otherwise positioned in via 530. For example, wires 507 and 509 may be routed between the FS 110 and FD 120 using vias 530. Optionally, another electrically conductive structure 511 (e.g., a wire) may straddle span 390 over first relaxation structure 111 and may have a profile 525 over the span 390. Wire 511 may be routed through one or more of the vias 530. A surface 110s of FD 110 may include one or more components 550 that may be electrically coupled with electrically conductive structures such as wire 511, wire 507, wire 381 or other and one or more of the vias 530 may be used to route electrically conductive structures to the one or more components 550 mounted on surface 110s. For example, wire 507 may be electrically coupled with component 550 and routed through via 530 for electrical connection with a structure on FD 120, such as wire 381.

Referring now to FIG. 5B, in some examples, a strain relief 500 may be connected with a component 560 and an end 521 of wire 381 may be electrically coupled with the component and connected 520 with the strain relief 500. Here, strain relief 500 is not connected with FD 120. A component mounted strain relief, such as 500, may be used to prevent strain on wire 381 from causing a wiring failure such as a short, open, or intermittent and/or prevent the wire 381 from being pulled out or otherwise dislodged from its electrical connection with component 560.

Moving now to FIGS. 5C-5E, an alternative configuration may include a second relaxation structure 522 positioned at flexure point 150 and includes electrical connectors 553 and 557 disposed on first and second sides 151 and 152 respectively, and also includes an electrically conductive structure 581 that straddles span 390. FD 120 may comprise separate segments that are positioned on sides (151, 152) with each segment including a connector 551 and 555 which are configured to mate or otherwise electrically and mechanically couple with connectors 553 and 557 to establish an electrical connection with electrically conductive structures 552 and 554 (e.g., wires or conductive traces) in FD 120. Electrically conductive structure 581 (wire 581 hereinafter) may be a wire, an electrically conductive trace or other structure. Wire 581 may have the profile 505 as described above. In some examples, wire 581 may be positioned internal to second relaxation structure 522 (see FIG. 5C), may be positioned over second relaxation structure 522 (see FIG. 5D), or may be positioned under second relaxation structure 522 (see FIG. 5E). Other structures such as components, strain reliefs, nodes, bonding pads, vias, encapsulating structures are not depicted in FIGS. 5C-5E for purposes of explanation; however, one or more of those structures may be included with the examples depicted in FIGS. 5C-5E. Connectors (551, 555, 557, 553) may be male and female and may be implemented using any suitable connector technology. Connectors (551, 555, 557, 553) may include pins, terminals or other structures that allow an electrical connection to be made between electrically conductive structures in FD 120 and the connectors. Connectors (551, 555, 557, 553) may include a wide variety of pitch and circuit sizes, may include ZIF and Non-ZIF actuators, and may include covers or other structures that allow for secure connection between terminals of the connectors and FD 120. Second relaxation structure 522, FD 120 or both may be made from flexible printed circuitry (FPC), flat flexible cable (FFC) or other type of flexible substrates suitable for electronics, for example.

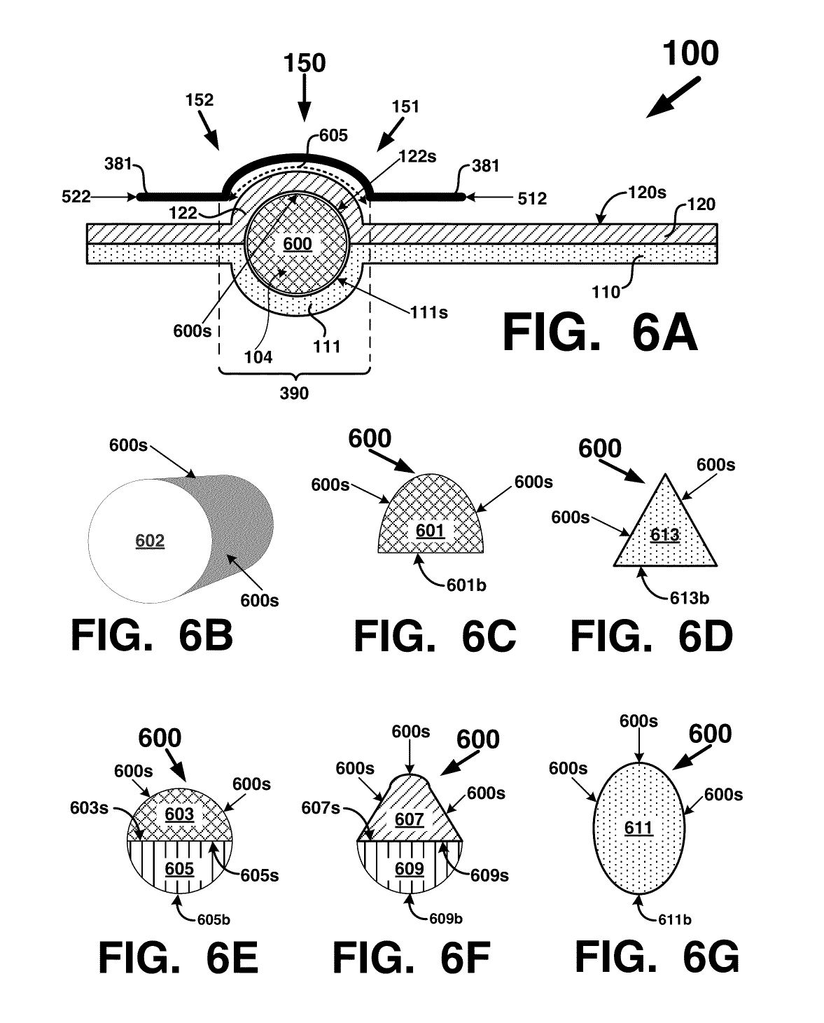

Attention is now directed to FIG. 6A where one example of a mandrel 600 is depicted. Mandrel 600 may be positioned in space 104 between the first and second relaxation structures 111 and 122. A shape of mandrel 600 may be selected to set a profile 605 of the second relaxation structure 122. Mandrel 600 may be positioned in space 104 to prevent second relaxation structure 122 from collapsing and/or deforming into a contour or profile that may adversely affect operation of flexure point 150 when the wearable device 100 is flexed 102 (see FIG. 1B). In some examples, one or more surfaces 600s of mandrel 600 may be in contact, permanently or intermittently, with surface 122s, surface 111s or both. Mandrel 600 may be made from a variety of materials including but not limited to metals, metal alloys, plastics, foam, wood, rubber, glass, composite materials, synthetic materials, Teflon or equivalent materials, and paper, just to name a few. Mandrel 600 may be configured to be deformable (e.g., foam) or non-deformable (e.g., metal). A plurality of the mandrels 600 may be used and mandrel's 600 may vary is dimensions and shape among a plurality of flexure points 150 (see FIGS. 1C and 1D).

In FIGS. 6B-6G, non-limiting examples of different configurations for mandrel 600 are depicted. In FIG. 6B, mandrel 602 may be cylindrical as in a solid cylinder or as in a cylindrical tube, for example. In FIG. 6C, mandrel 601 may have an arcuate shape and a surface 601b may contact portions of surface 111s. In FIG. 6D, mandrel 613 may have triangular shape and a surface 613b may contact portions of surface 111s. Triangular shape for mandrel 613 may be used to set a profile of second relaxation structure 122 (e.g., 150e-150k of FIG. 1D). In FIG. 6E, a composite mandrel may include portions 603 and 605 joined at surfaces 603s and 605s and may have an overall circular or cylindrical shape. A surface 605b of portion 605 may contact portions of surface 111s. In FIG. 6F, a composite mandrel may include portions 607 and 609 joined at surfaces 607s and 609s and may have an arcuate or conical shape for portion 607 and a semi-circular shape for portion 609. A surface 609b of portion 609 may contact portions of surface 111s. In FIG. 6G, mandrel 611 may have an ovoid shape and surface 611b may contact portions of surface 111s. Composite mandrels may have portions that are made from different materials. The mandrels depicted may include materials or be coated with a material that lubricates one or both of the relaxation structures (111, 122) and/or reduces friction between surfaces of the mandrel and one or both of the relaxation structures (111, 122).

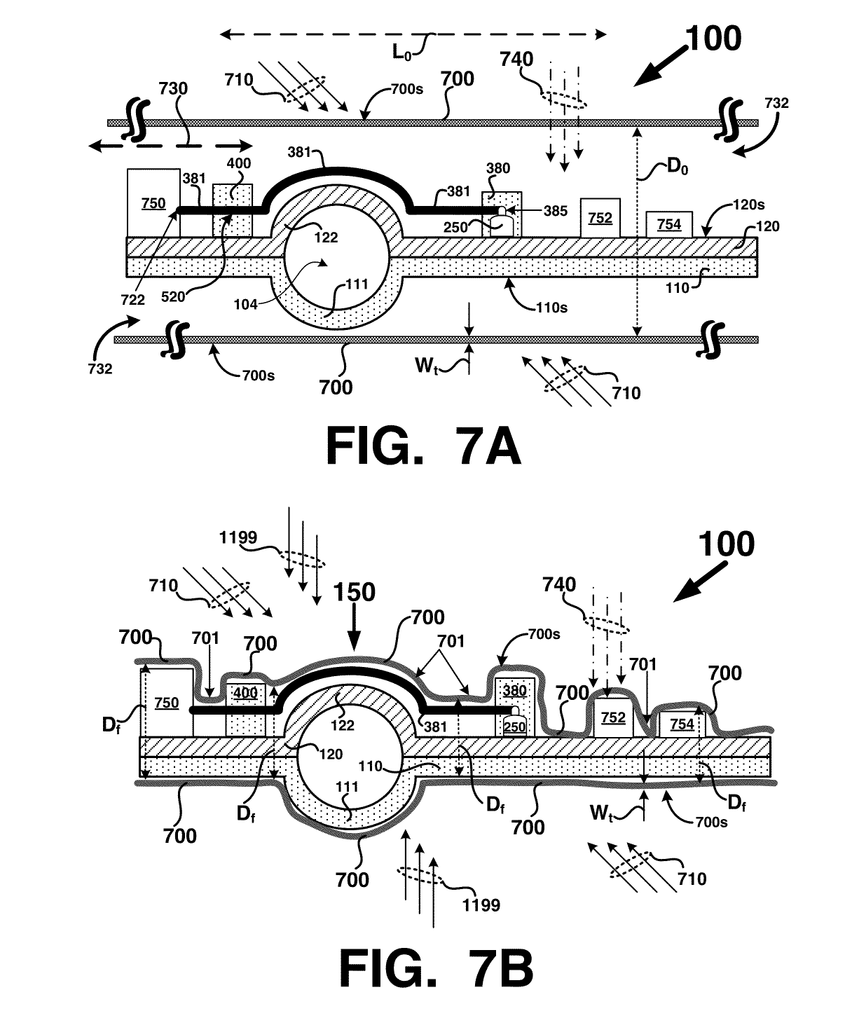

FIG. 7A depicts a cross-sectional view of one example of a flexible and electrically non-conductive cover 700 (cover 700 hereinafter). FD 120, FS 110 and associated structures carried by FD 120 and FS 110 are positioned 730 in an interior 732 of cover 700. Cover 700 may include a pre-shrink dimension D₀ that is large enough to accommodate insertion of the aforementioned structures (e.g., device 100). As will be described below, cover 700 may comprise a single section of material or a plurality of sections which may be made from different materials. Suitable flexible materials for the cover 700 and/or its plurality of sections include but are not limited to shrink tubing, heat shrink tubing, thin wall heat shrink tubing, ultra-thin wall heat shrink tubing, medical grade tubing, high temperature medical grade tubing, Polyester (PET) heat shrink tubing, Polyether tubing, heat shrinkable polyolefin tubing, ultra-thin wall Polyolefin heat shrink tubing, PBEAX heat shrink tubing, PEBA heat shrink tubing, Polyvinylidene Fluoride (PVDF) tubing, Silicone tubing, Polyethylene (PE) tubing, Polytetrafluorethylene (PTFE) tubing, Teflon tubing, fluoroelastomer tubing, and the like, for example. The medical grade tubing and/or high temperature medical grade tubing may be shrunk by applying heat (e.g., 710) as described herein. Material properties for the cover 700 and/or it plurality of sections may include but are not limited to low shrinkage in a longitudinal direction (e.g., a direction L₀ that is perpendicular to D₀), conformal (e.g., conformally covering as in FIG. 7B), surface finish, tough, tight fitting, durable, dimensional stability (e.g., due to heating during manufacturing and post manufacturing), stable, flexibility, transparency to light, and thin or ultra-thin wall thicknesses (e.g., W_{T}), shrink ratio (e.g., in a range from about 1.5:1 to about 4.5:1), temperature stability (e.g., from about 100° C. to about 265° C.), resistance to water and/or moisture, just to name a few. For example, shrink ratios from about 2:1 minimum to about 4:1 maximum may be desirable material properties along with a wall thickness W_{T} of about 0.1 mm and a temperature stability of the material at molding temperatures for the overmolding 1200. For example, if cover 700 has an inside diameter (ID) of about ⅜″ prior to heat 710 being applied to cover 700, then after heating, the ID may shrink to about 0.187 inches, (e.g., about a 2:1 shrinkage ratio). Other examples may include a before heating ID of about ½″ and an after heating ID of about ¼″ or about ¾″ ID before and about ⅜″ ID after. A temperature at which the cover 700 and/or its plurality of sections shrink may be about 90° C. Operating temperatures for the cover 700 and/or its plurality of sections may be in a range from about −55° C. to about 274° C. An actual size of the assembly that is inserted 730 within the interior diameter D₀ will be application dependent, however a product size from about 0.250″ to about 0.5″ is one non-limiting example of dimensions of a work piece (e.g., 100) or other assembly to be covered by cover 700.

Here, FD 120 may include structures including but not limited to components 750-754, wire 381, nodes 250, encapsulating structure 380, and strain relief 400. Although not depicted, FS 110 may also include structures. Cover 700 may be transparent 740 to allow for visual or machine inspection for quality control or other manufacturing purpose. Transparent 740 may include optically transparent. In some applications a light sensor (e.g., PIN Diode) or light emitting component (e.g., LED) may be mounted to FD 120 and cover 700 being transparent 740 may allow for light to be received or transmitted through cover 700. In some examples, one or more portions of cover 700 may be transparent 740.

In FIG. 7B, after positioning 730 in the interior 732 (e.g., after Final Assembly Test & Packaging—FATP), heat 710 and/or some other process may be applied to the cover 700 to shrink cover 700 in one or more dimensions. Upon shrinking, cover 700 may partially or completely conformally cover 701 structures including but not limited to the FS 110, FD 120, and other structures carried by the FS 110 and FD 120, such as components 750-754, wire 381, nodes 250, encapsulating structure 380, and strain relief 400. Cover 700 or the one or more sections of cover 700 may be made from a material that when heated 710 or otherwise caused to shrink, shrinks cover 700 or its one or more section in a dimension by a ratio (e.g., of at least about 1.5:1). For example, shrinkage of cover 700 in a ratio of about 2:1 to about 4:1 may be desirable for some applications. Actual ratios may be application dependent, material dependent or process dependent and are not limited by the examples herein. In some examples, after shrinking cover 700, or one or more of its sections, subsequent fabrication steps may involve high temperatures. Therefore, in some applications a material for cover 700, or its one or more sections, may be selected to be mechanically stable over a temperature range from about 100° C. to about 300° C. Although heat 710 is depicted as one method for causing the cover 700 to shrink, the present application is not limited to heating 710 and other processes or combinations of processes may be used. For example, a composition of matter, such as a chemical or solvent may be applied to cover 700 to cause shrinking. In some examples, a vacuum may be applied to cover 700 (e.g., to evacuate air from interior 732) to cause cover to collapse and/or shrink in a dimension that conformally covers some or all of the structure described above. After applying the vacuum, heat, chemicals, a composition of matter or other may be applied to cover to cause additional shrinking, to set the shrinking that has already occurred, or to cure the cover 700 to cause the shrinking to set. In other examples, cover 700 may be irradiated by one or more wavelengths of light or other forms of electromagnetic radiation.

After shrinking, pre-shrink dimension D₀ may be reduced to a post-shrink dimension D_{F}. Post-shrink dimension D_{F} may vary based on the components or other structures being covered and/or conformally covered by the cover 700 as depicted in FIG. 7B. For example, D_{F} is greater at conformal covering of component 750 than at conformal covering of component 754 or at conformal covering of wire 381 on first side 151.

FIG. 8A depicts a cross-sectional view of cover 700 having FD 120 and FS 100 and their respective flexure points 150a-150d positioned in its interior 732. For purposes of explanation, components and other structures that may be carried by FD 120 and FS 100 are not depicted in FIGS. 8A-8B. Cover 700 may subsequently be heated 710 or subjected to some other process to cause shrinking. In FIG. 8B, one example of a cover comprised of a plurality of cover sections is depicted. Here, cover sections 801, 803, 805, and 807 have a portion of FD 120 and FS 100 and their respective flexure points 150e-150k positioned in their respective interiors 732. In some examples, one or more of the cover sections may overlap each other as depicted by dashed ovals 811, 813, and 815. In some examples, after shrinking the cover sections (801, 803, 805, and 807) the overlap (811, 813, and 815) between some or all of the cover sections (801, 803, 805, and 807) may be retained. Materials for one or more of the cover sections (801, 803, 805, and 807) may be the same or different and one or more of the cover sections (801, 803, 805, and 807) may be transparent 740 as described above.

Pre-shrink dimension D₀ of one or more of the cover sections (801, 803, 805, and 807) may be the same or different. One or more of the cover sections (801, 803, 805, and 807) may be selected to have a first pre-shrink dimension D₀ configured to accept portions of FD 120 and FS 100 and also be configured to fit within another cover section having a second pre-shrink dimension D₀ that is larger than the first pre-shrink dimension D₀, such as cover sections 801 and 803 fitting within cover section 805. Multiple cover sections may be shrunk all at the same time or in some sequenced order. For example, given cover sections (801, 803, 805, and 807), cover sections 801 and 803 may be positioned over their respective portions of FD 120 and FS 110 and then have heat 710 or other process applied to shrink 801 and 803. Next, cover section 805 may be positioned and shrunk, followed by cover section 807 being positioned and then shrunk.

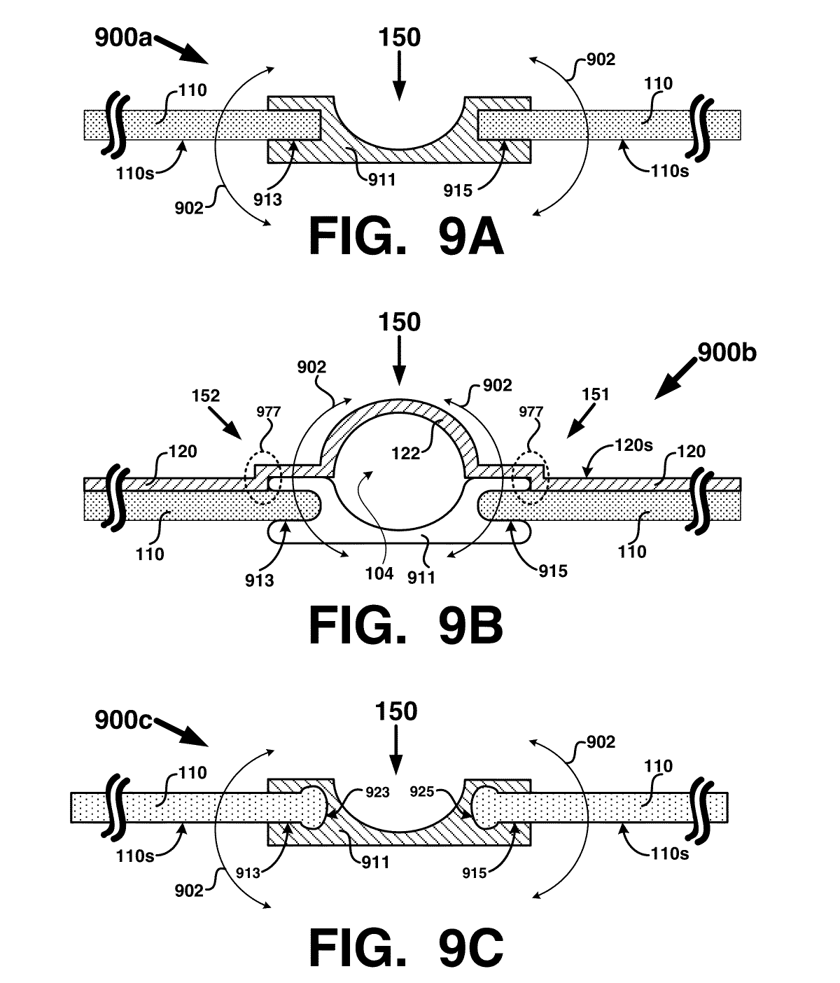

Reference is now made to FIGS. 9A-9C where cross-sectional views depict examples 900a-900c of alternative configurations for the first relaxation structure denoted as 911. First relaxation structure 911 may be positioned at flexure point 150 as describe above. Portions 913 and 915 of first relaxation structure 911 may be configured to connect with FS 110. For example, slots, grooves, apertures or the like in structure 911 may be configured to receive a portion of FS 110. Materials for the first relaxation structure 911 and the FS 110 may be the same or different. Glue, adhesives, crimping, stamping, fasteners or the like may be used to connect (913, 915) 911 and FS 110 to one another. First relaxation structure 911 may be configured to allow flexing 902 in a manner similar to or identical to flexing 102 as described above. First relaxation structure 911 may be used instead of an integrally formed first relaxation structure 111 as described above. First relaxation structure 911 may be selected for application specific properties and/or materials. FS 110 may be made from a first material (e.g., a metal or metal allow) and first relaxation structure 911 may be made from a second material (e.g., rubber or an elastomer) that is different than the first material. First relaxation structure 911 may be selected for properties including but not limited to durability, number of flexure 902 cycles, resistance to heat or other processing environments, and specific flexing properties, just to name a few.

FIG. 9B depicts another configuration 900b where first relaxation structure 911 may include arcuate surfaces as denoted in dashed ovals 977 that may be used to provide a smooth and/or conformal surface for FD 120 which may be connected with one or more portions of first relaxation structure 911. FIG. 9B also depicts an example of how the first and second relaxation structures (911, 122) operate to impart flexing 902 at flexure point 150. FIG. 9C depicts yet another configuration 900c where FS 110 includes portions 925 including a shape configured to connect (913, 915) and retain FS 110 in first relaxation structure 911.

Turning now to FIGS. 10A-10B, where profile and cross-sectional views respectively, depict one example of a partially assembled wearable device 100. In FIGS. 10A-10B wearable device 100 includes a plurality of components denoted as 1010-1022 and 1011-1017. FS 110 and FD 120 include a plurality of flexure points denoted as 150a-150f. For purposes of explanation details such as the first and second relaxation structures (111 and/or 911, 122) are not depicted in FIGS. 10A-10B. One or more of the flexure points 150 on wearable device 100 may be positioned at locations that suit application specific needs or may be customized for a bespoke application. As one example, the plurality of flexure points 150a-150f may be selected to allow wearable device 100 to be flexibly worn about a body portion 1050 or some other structure. Body portion 1050 may be a cross-sectional profile of a body part such as a wrist, arm, neck, leg, ankle or the like, for example. Component 1010 may be a power source such as a rechargeable power source (e.g., a Lithium Ion battery) and component 1010 may be rigid or un-flexible. Therefore, it may be a matter of design choice to place flexure points 150c and 150d on either side of component 1010 so that wearable device 100 may bend or otherwise flex proximate the positions of flexure points 150c and 150d. Due to a shape or contour of body portion 1050 it may be necessary to design in flexure at side portions of body portion 1050 denoted as 1050a-1050d to accommodate different sizes for body portion 1050 in different sized users, for example. Therefore, wearable device 100 may have flexure points at 150e and 150f to approximately match anticipated flexure for side portions 1050a and 1050b and may have flexure points at 150b and 150a to approximately match anticipated flexure for side portions 1050c and 1050d. A size, shape, position, configurations and materials for the FS 110, FD 120, relaxation structures (111, 911, 122) and one or more flexure points 150 will be application specific and are not limited by the exampled described herein.

Advancing now to FIGS. 10C-10D, in FIG. 10C a partially assembled wearable device 100 includes FS 110, FD 120, and a plurality of flexure points 150a-150f (e.g., as depicted in FIGS. 10A-10B). The first and second relaxation structures (111 or 911, 122) that may define flexure points 150a-150f may have different sizes and profiles. FS 110 and FD 120 may be connected with each other as described above. The partially assembled configuration depicted in FIG. 10C may be used to implement the wearable device 100 depicted in FIGS. 10A-10B. Moving down to FIG. 10D, partially assembled wearable device 100 may additionally include components 1010-1015 mounted to FD 120 and optionally to FS 110 (not shown). Subsequently, partially assembled wearable device 100 may be inserted 730 or otherwise positioned in interior 732 of cover 700 as described above and process such as heating 710 or other process may be applied to cover 700 to shrink cover 700 as described above. As will be described below, a flexible overmolding or other flexible material that retains its shape after being flexed into a configuration may be applied 1190 to the exterior surface 700s of cover 700. Other structures such as wires, conductive traces, and the like are not depicted in FIGS. 10C-10D, but may be included as described above.

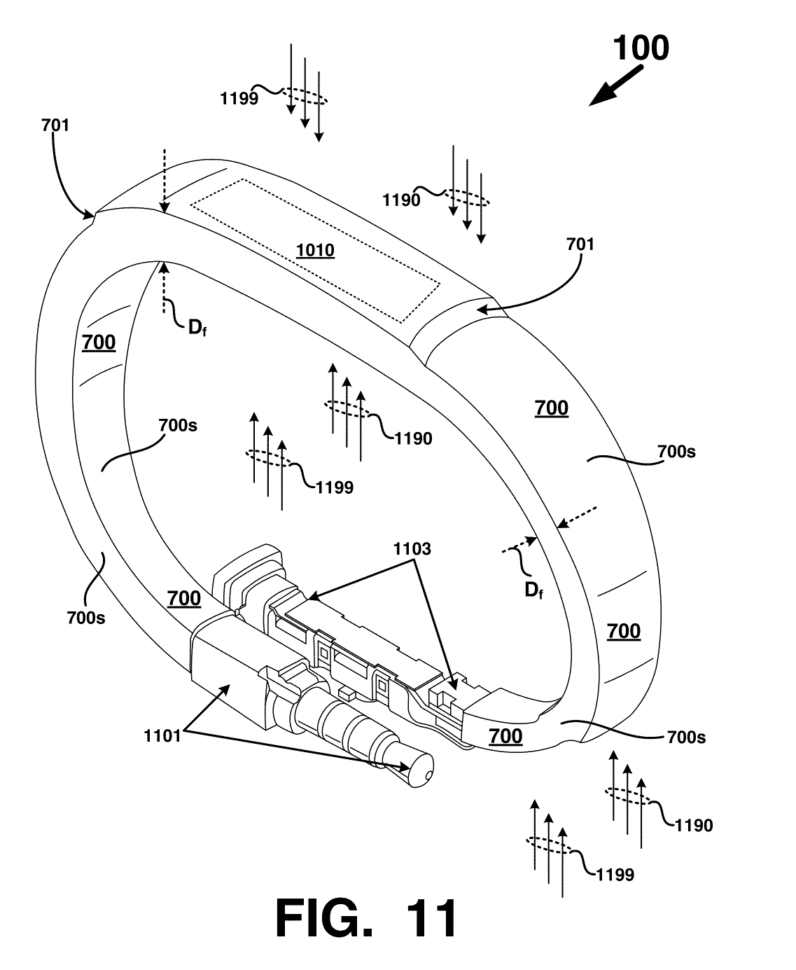

FIG. 11 depicts a profile view of one example of a partially assembled wearable device 100 including cover 700 after the shrinking process. Here, some or all of components 1010-1015 are completely covered by cover 700 after the shrinking process, as depicted by dashed outline for covered component 1010. Post shrinking, cover 700 may have variations in its post-shrink dimensions D_{F} that may be due in part to the conformal 701 covering of components of different dimensions. In some examples, portions of partially assembled wearable device 100 may not be covered by cover 700 as denoted by portions 1101 and 1103. The cover 700 may have its length or other dimension adjusted so as to not cover portions such as 1101 and 1103 upon shrinking or portions 1101 and/or 1103 may be masked or cover 700 may be removed (e.g., by cutting) from those portions. Post shrinking, cover 700 may be subjected to additional processing 1190, such as curing or applying a coating to cover 700, for example. As one example, process 1190 may apply a material (e.g., to promote adhesion) on cover 700 to prepare the cover 700 for a subsequent processing step, such as applying another layer of material in cover 700. As will be described below, a flexible overmolding 1200 may be applied 1199 to an exterior 700s of covering 700.

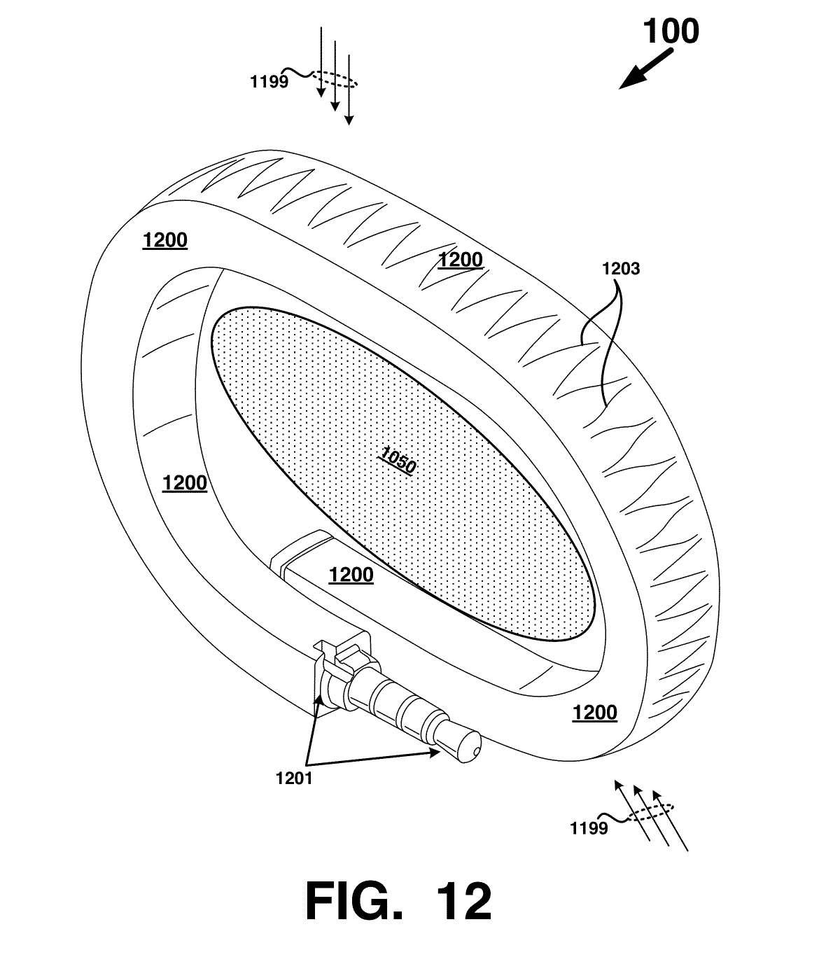

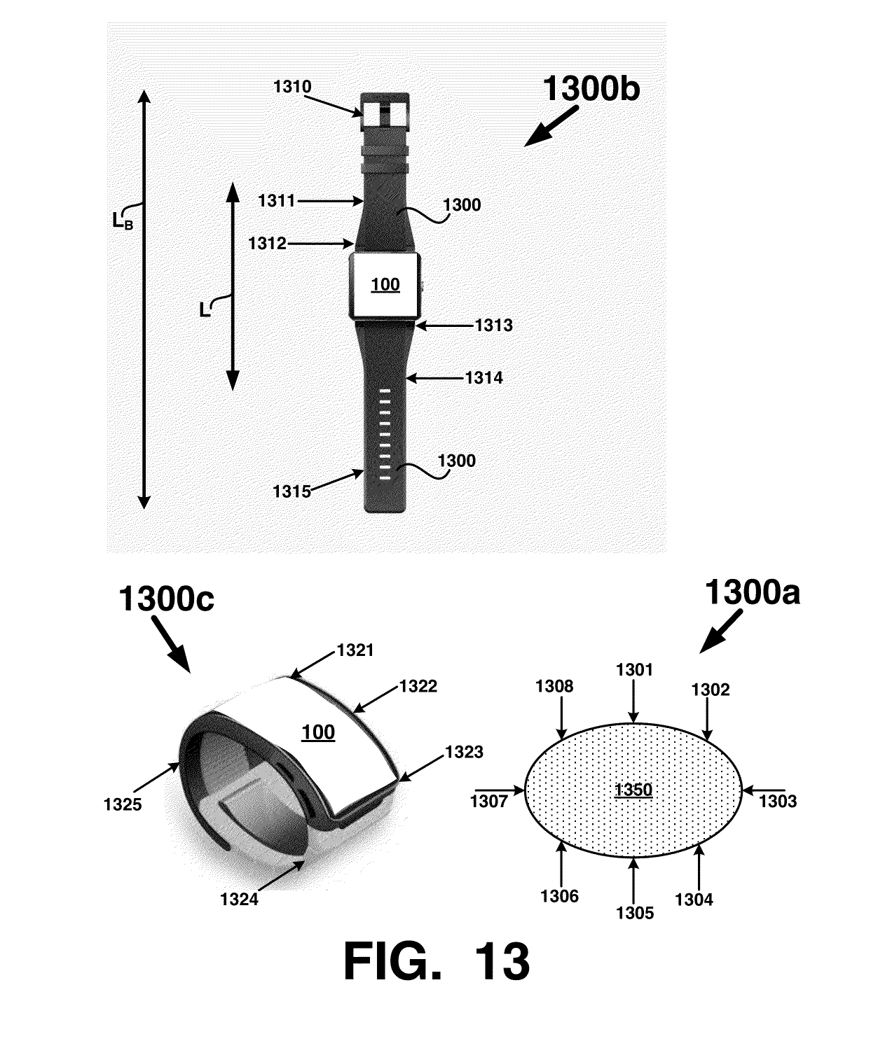

Turning now to FIG. 12 wear a profile view of one example of a flexible overmolding 1200 is applied 1199 to wearable device 100. Flexible overmolding 1200 may be applied over cover 700 of FIG. 11 and may be applied as a single layer of material or a plurality of layers of material. Cover 700 or multiple sections thereof may be configured to remain dimensionally stable at temperatures that the flexible overmolding 1200 is applied at, as described above. Flexible overmolding 1200 may include functional and/or ornamental (esthetic) elements denoted as 1203. One or more portions of wearable device 100 may not be covered by flexible overmolding 1200, cover 700, or both, as denoted by 1201. FS 110, cover 700, multiple sections of cover 700, FD 120, and flexible overmolding 1200 may be designed to be flexible and one or more of the aforementioned may be designed to retain its shaped after being flexed into a configuration such as depicted in FIG. 12 where the configuration of wearable device 100 has been flexed to conform to body portion 1050 and retains its shape after being flexed into the configuration. FS 110 and/or flexible overmolding 1200 may be made from a material that allows it to retain its shape after being flexed into a configuration or profile. FS 110 may comprises a material including but not limited to a metal, a metal allow, a flat substrate, a flat metal substrate, a composite substrate, a carbon fiber substrate, a spring, and a flat spring, just to name a few, for example. One or more portions of FS 110 may be inflexible (e.g., stiff or rigid) or less flexible than other portions of FS 110 and those portions may be made from a material that is different than the flexible portions of FS 110. As one example, some portions may be made from a flexible spring metal and other portions may be made from a stiff metal. Flexible overmolding 1200 may be made from an electrically non-conductive material. Flexible overmolding 1200 may be made from materials designed for specific properties including but not limited to water resistance, hydrophobic, resistance to chemicals or solvents, resistant to body fluids (e.g., sweat and oils), non-allergenic, temperature resistance, submersible, outgassing, resistance to abrasion, infrared light resistance, and UV light resistance, just to name a few.

Transitioning now to FIG. 13 were views of different examples 1300b-1300c of wearable devices 100 configured to be flexibly worn on a portion of 1350 of a structure (e.g., a user's body) are depicted. Here, in configuration 1300a, one or more points 1301-1308 of portion 1350 may candidates for placement of flexure points (e.g., 150) on a wearable device 100 configured to be flexibly worn or otherwise mounted to portion 1350. In configurations 1300b and 1300c, wearable device 100 may be a smart watch, data capable strap band, or other portable wearable device. In configuration 1300b, device 100 may be designed to have flexure points 1311 and 1312 on a buckle side 1310 of a band 1300 and flexure points 1313 and 1314 on a strap side 1315 of the band 1300. Those flexure points may be selected to best match one or more of the points 1301-1308 of portion 1350. In contrast, in configuration 1300c, device 100 may include flexure points 1321-1325 that are selected to best match one or more of the points 1301-1308 of portion 1350 and number and position of those flexure points may best be suited for a wearable device 100 that lacks a buckle and strap of configuration 1300b. In configuration 1300b the length L of device 100 may span at least a portion of an overall length L_{B} of band 1300.

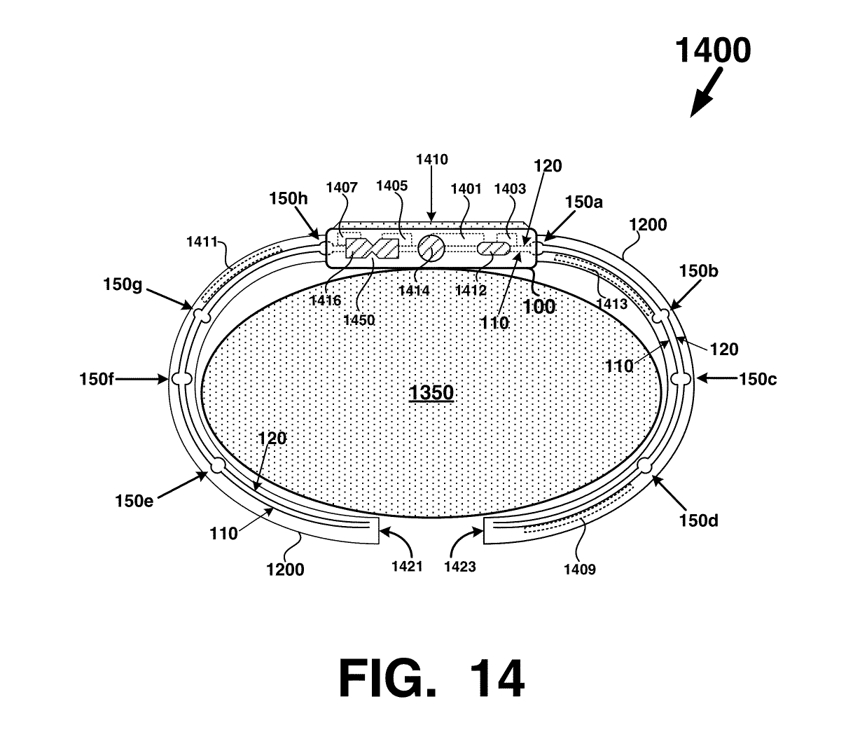

Moving now to FIG. 14 were a cross-sectional view of an example 1400 of a wearable device 100 flexibly mounted to a portion of a structure 1350 is depicted. For purposes of explanations, cover 700 is not depicted in FIG. 14. Device 100 may be a smart watch, data capable strap band, or other portable wearable device configured to be worn on structure 1350 (e.g., a body portion of a user's body). Device 100 may include FS 110, FD 120, a plurality of flexure points 150a-150g, a plurality of components 1401, 1403, 1405, 1407, 1409, 1411, 1412, 1414, and 1416 some of which may not be connected with FD 120 and/or FS 110. Device 100 may include chassis 1450 and a display system 1410 (e.g., an OLED or LCD). Components 1412, 1414 and 1416 may be switches or actuators configured to control one or more functions of wearable device 100 such as answering a phone call, sending an email, sending a text, controlling playback of media or other content, for example. Structure 1350 may be a wrist of a user and flexure points 150a-150g may be positioned in device 100 to accommodate flexing device 100 onto or off of structure 1350. Portions 1421 and 1423 may or may not include a latching structure such as a buckle and strap, clasp, or the like. Portions 1421 and 1423 may not have any structure and may be were the flexible overmolding 1200 terminates. Some of the components may be mounted to surface 120s of FS 110 such as component 1413. Vias, wiring, or other electrically conductive structures described above may be used to electrically couple components/structures on FS 110 with components/structures on FD 120. Here, flexure points may be placed as necessary to accommodate proper mounting to structure 1350 and/or based on structure of the wearable device 100. As one example, chassis 1450 may be ridged or not as flexible as other portions of device 100. Therefore, flexure points 150a and 150h may be positioned to allow flexing to begin where the chassis 1450 ends.

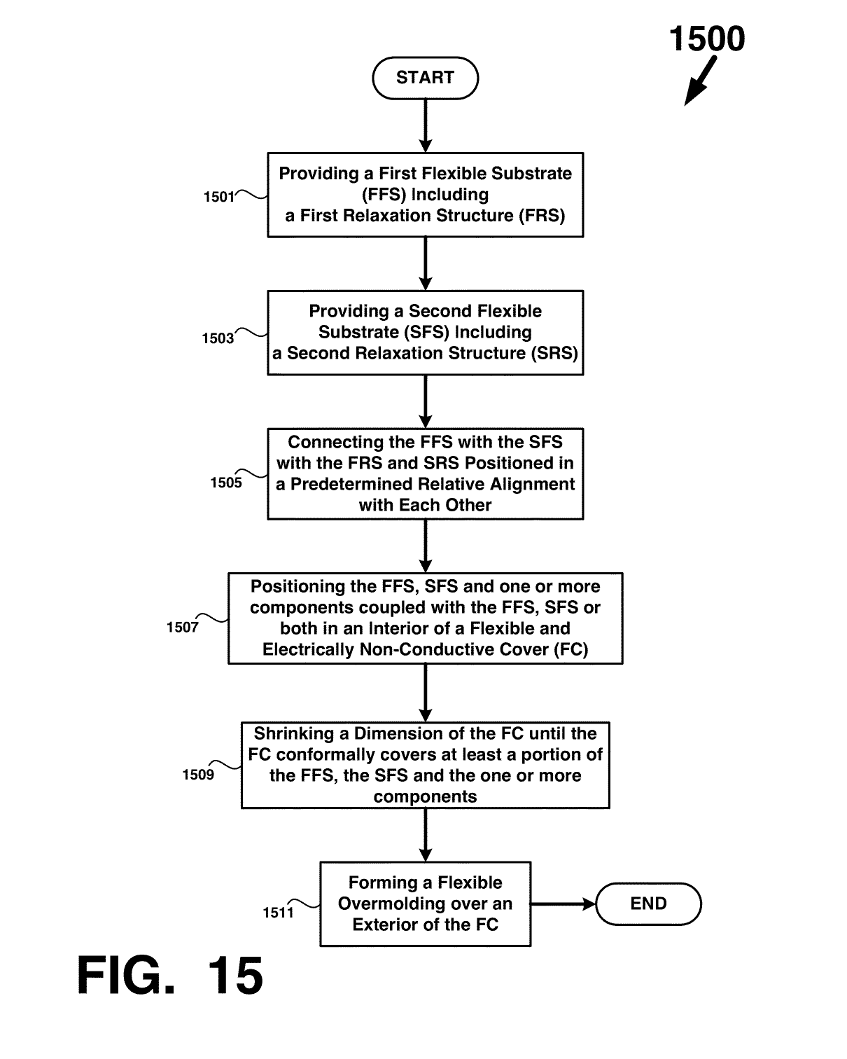

FIG. 15 depicts one example of a flow diagram 1500 for a method for fabricating a wearable device, such as device 100 as depicted herein. At a stage 1501 a first flexible substrate (FFS) (e.g., FS 110) that includes a first relaxation structure (FRS) (e.g., 111 or 911) is provided. If the first relaxation structure 911 is included, stage 1501 or a prior stage may be used to connect the first relaxation structure 911 and the FRS with each other as depicted in FIGS. 9A-9C. At a stage 1503 a second flexible substrate (SFS) (e.g., FD 120) that includes a second relaxation structure (SRS) (e.g., 122) is provided. At a stage 1505 the first and second flexible substrates (e.g., 110, 120) may be connected with the first and second relaxation structures (e.g., 111 or 911, 122) positioned in a predetermined relative alignment with each other (e.g., at a flexure point 150). At a stage 1507 the FFS, the SFS and any components coupled with the FFS, the SFS or both may be positioned in an interior of a flexible and electrically non-conductive cover (FC) (e.g., cover 700 or one or more sections 801-807) as described herein. Prior to the stage 1507, one or more components (e.g., circuitry, structure, connectors, wiring, mandrels, electrically conductive traces, electrically conductive structures, and the like) may have already been mounted to or otherwise connected with the FFS, the SFS or both as described above. At a stage 1509, the FC is shrunk in a dimension (e.g., its diameter) until the FC conformally covers at least a portion of the FFS, the SFS, and the one or more components. During the shrinking, one or more dimensions are reduced from an initial dimension (e.g., D₀) to a final dimension (e.g., D_{f}). In that the FRS and SRS are integrated with the FFS and SFS respectively, the FC may also conformally cover at least a portion of the FRS and SRS. Shirking the FC may comprise processes other than applying heat or heating and may also comprise shrinking one or more sections of FC in a sequence or all sections at one time. For example, sections 801-807 of FIG. 8B may undergo the shrinking at the same time or one or more sections may undergo the shrinking at different times. As one example, sections 801 and 803 may be shrunk first and then sections 805 and 807 may be shrunk second. When multiple sections of cover 700 are used (e.g., as in FIG. 8B), the stages 1507 and 1509 may be repeated for one or more of the sections. For example, the positioning at the stage 1507 may be used for sections 801 and 803, followed by the shrinking of sections 801 and 803 at the stage 1509. Next, the positioning at the stage 1507 may be repeated for sections 805 and 807, followed by the shrinking of sections 801 and 803 at the stage 1509. After one or more sections have undergone shrinking, a visual and/or machine inspection may be performed and any defective section re-worked or replaced, for example. Optionally, after one or more sections have undergone shrinking or at the completion of all shrinking, components or other structure may be inspected visually and/or by machine through an optically transparent section (e.g., 740) of cover 700. At a stage 1511 a flexible overmolding (e.g., 1200) may be formed or otherwise applied (e.g., 1199) over at least a portion of an exterior (e.g., 700s) of the FC 700. A variety of processes may be used to apply the flexible overmolding 1200 including but not limited to spraying, depositing, dipping, molding, casting, layering, and painting, just to name a few. The stages depicted in flow diagram 1500 may occur in an order different than that depicted in FIG. 15 and one or more stages may be repeated. Furthermore, some stages may not be performed. Moreover, the stages may not be performed at a same fabrication/manufacturing location.

As a person skilled in the art will recognize from the previous detailed description and from the drawing FIGS. and claims set forth below, modifications and changes may be made to the embodiments of the present application without departing from the scope of this present application as defined in the following claims.

Although the foregoing examples have been described in some detail for purposes of clarity of understanding, the above-described inventive techniques are not limited to the details provided. There are many alternative ways of implementing the above-described techniques or the present application. The disclosed examples are illustrative and not restrictive.

1. A wearable structure, comprising:
a flexible substrate (FS) including a first relaxation structure, the FS configured to retain its shape after being flexed into a configuration;
a flexible dielectric (FD) including circuitry, electrically conductive traces, a bonding pad, and a second relaxation structure, a portion of the circuitry is interconnected using the electrically conductive traces and another portion is interconnected using a wire that straddles the second relaxation structure and is electrically connected with the bonding pad;
an encapsulation structure positioned adjacent to the second relaxation structure and covering the bonding pad and a portion of the wire;
a strain relief positioned adjacent to the second relaxation structure and in contact with a portion of the wire; and
a flexible and electrically non-conductive cover including one or more sections that partially or completely conformally covers the FS, the FD, the encapsulation structure, and the strain relief.

2. The structure of claim 1, wherein the first relaxation structure is integrally formed in the FS.

3. (canceled)

4. The structure of claim 1, wherein a first end of the wire is electrically connected with the bonding pad and a second end of the wire is electrically connected with an electrical component.

5. (canceled)

6. The structure of claim 1, wherein a first end of the wire is electrically connected with the bonding pad and second end of the wire is electrically connected with another bonding pad.

7. The structure of claim 6, wherein the bonding pad and the another bonding pad are positioned on opposite sides of the second relaxation structure.

8. The structure of claim 1, wherein the second relaxation structure and the first relaxation structure are disposed adjacent to each other.

9. The structure of claim 1, wherein the second relaxation structure and the first relaxation structure are disposed adjacent to each other and positioned at a flexure point in a wearable device.

10. The structure of claim 1, wherein portions of the one or more sections conformally cover portions of a selected one or more of the FS, the FD, the encapsulation structure, or the strain relief.

11. The structure of claim 1, wherein the wire has a profile over a portion of its span that approximates a profile of the second relaxation structure.

12. The structure of claim 1, wherein at least one of the one or more sections is transparent.

13. The structure of claim 1, wherein the second relaxation structure is integrally formed in the FD.

14. The structure of claim 1, wherein a contour of the second relaxation structure approximately matches another contour of a loop mandrel.

15. The structure of claim 1, wherein the FD comprises a component selected from the group consisting of flexible printed circuitry (FPC) and flat flexible cable (FFC).

16. The structure of claim 1, wherein the FS comprises a component selected from the group consisting of a metal, a flat substrate, a flat metal substrate, a spring, and a flat spring.

17. The structure of claim 1, wherein the one or more sections are made from a material that when heated, shrinks in a dimension by a ratio of at least 1.5:1.

18. The structure of claim 17, wherein the material after shrinking, is mechanically stable over a temperature range from about 100° C. to about 300° C.

19. The structure of claim 1 and further comprising:
a flexible overmolding in contact with and covering the one or more sections.

20. The structure of claim 1, wherein the FS comprises at least two separate sections and the first relaxation structure is connected with a portion of one section and a portion of another section.

21. The structure of claim 1, wherein the second relaxation structure comprises a service loop.

22. A method for fabricating a wearable device, comprising:
providing a first flexible substrate (FFS) configured to retain its shape after being flexed into a configuration, the FFS including a first relaxation structure;
providing a second flexible substrate (SFS) including a second relaxation structure;
connecting the FFS and the SFS with each other with the first relaxation structure and the second relaxation structure positioned in a predetermined alignment relative to each other;
positioning the FFS, the SFS and one or more components coupled with the FFS, the SFS or both in an interior of a flexible and electrically non-conductive cover (FC);
shrinking a dimension of the FC until the FC conformally covers at least a portion of the FFS, the SFS and the one or more components; and
forming a flexible overmolding over an exterior of the FC.
